(19) United States
(12) Patent Application Publication
(10) Pub. No.: US 2005/0231258 A1
(43) Pub. Date: Oct. 20, 2005

(54) Static flip-flop circuit

(76) Inventors: Yasuyuki Suzuki, Minato-ku (JP); Shigeki Wada, Minato-ku (JP); Yasushi Amamiya, Minato-ku (JP)

Correspondence Address: SUGHRUE MION, PLLC, 2100 PENNSYLVANIA AVENUE, N.W., SUITE 800, WASHINGTON, DC, 20037, US

(21) Appl. No.: 10/519,457

(22) PCT Filed: Jun. 24, 2003
(86) PCT No.: PCT/JP03/07963

§ 371 Date: Dec. 29, 2004

(30) Foreign Application Priority Data
Jul. 1, 2002 (JP) 2002-192068

(51) Int. Cl. H03K 3/037

(52) U.S. Cl. 327/218

(57) ABSTRACT

Master circuit 1 and slave circuit 2 are designed so that the transistors constituting data-hold differential pairs are smaller in size than the transistors constituting data reading differential pairs. Further, the flip-flop circuit is adapted to operate in an operating speed range in which the currents through the data-hold differential pairs are lower than the currents through the data reading differential pairs, and the currents through the data-hold differential pairs are equal to or lower than the permissible current level of the transistors that constitute the data-hold differential pairs.

### TECHNICAL FIELD

The present invention relates to a static flip-flop circuit having a data readout differential pair and a data-hold differential pair in both the master circuit side and the slave circuit side and renewing data input logical values in synchronism with a clock signal, and in particular, relates to a static flip-flop circuit using ECL (Emitter Coupled Logic) or SCFL (Source Coupled FET Logic) which assures high-speed operation.

### BACKGROUND ART

FIG. 1 is a circuit diagram showing an example of a conventional static flip-flop using ECL basic circuits.

Referring to FIG. 1, this conventional example of the static flip-flop circuit includes two latch circuits, master circuit 1 and slave circuit 2. Here, GND indicates a ground terminal, VEE indicates a power supply terminal and VCS indicates a constant-current source terminal.

Master circuit 1 includes: a data reading circuit composed of resistors R1 and R2, transistors Q1, Q2 and Q5; a data-hold positive-feedback circuit composed of resistors R1 and R2, transistors Q3, Q4 and Q6, transistors Q8 and Q9 and resistors R6 and R7; and a current source circuit composed of transistor Q7 connected to the common emitters of transistors Q5 and Q6 and resistor R5.

Slave circuit 2 includes: a data reading circuit composed of resistors R3 and R4, transistors Q10, Q11 and Q14; a data-hold positive-feedback circuit composed of resistors R3 and R4, transistors Q12, Q13 and Q15, transistors Q17 and Q18 and resistors R9 and R10; and a current source circuit composed of transistor Q16 connected to the common emitters of transistors Q14 and Q15 and resistor R8.

In this arrangement, transistors Q1 to Q7 and resistors R1, R2 and R5, and transistors Q10 to Q16 and resistors R3, R4 and R8 form series-gating configuration, each composed of differential pairs arranged at top and bottom. Transistors Q8 and Q9 and resisters R6 and R7, and transistors Q17 and Q18 and resisters R9 and R10 constitute an emitter follower circuit. The current source circuit for master circuit 1 and the current source circuit for slave circuit 2 are both connected to common constant current source terminal VCS so that a constant current flows through each current source circuit.

Here, data signal D inputs to the base of transistor Q1, complementary data signal DB inputs to the base of transistor Q2, clock signal CK inputs to the bases of transistors Q5 and Q15, complementary clock signal CKB is input to the bases of transistors Q6 and Q14, and output terminals Q′ and QB′ of master circuit 1 are connected to the input terminals (the bases of transistors Q10 and Q11) for slave circuit 2, thus, a static flip-flop circuit is configured. In this case, output terminals Q and Q′ are output terminals of true signals and output terminals QB and QB′ are output terminals for complementary signals.

Next, the operation of the static flip-flop circuit shown in FIG. 1 will be described.

When clock signal CK goes to the high level, transistor Q5 becomes conductive, so as to form a current path to the differential pair made up of transistors Q1 and Q2. Data signal D and complementary data signal DB input to master circuit 1 are inverted by the differential pair made up of transistors Q1 and Q2 and then level shifted through transistor Q8 and Q9 to be output at output terminals Q′ and QB′ of master circuit 1. At this moment, since transistor Q6 is applied with complementary clock signal CKB being in the low level, hence is non-conductive, no current will flow through the differential pair made up of transistors Q3 and Q4. As a result, the signals extracted at output terminals Q′ and QB′ of master circuit 1 will not be transmitted to slave circuit 2 but are held at output terminals Q′ and QB′.

Next, when clock signal CK goes to the low level with complementary clock signal CKB high, transistor Q6 becomes conductive to form a current path to the differential pair made up of transistors Q3 and Q4. Resultantly, the signals extracted at output terminals Q′ and QB′ of master circuit 1 are transmitted to transistors Q3 and Q4 and transistors Q10 and Q11.

Since positive feedback is effected in the differential pair made up of transistors Q3 and Q4 by the emitter follower circuit, the output signals from master circuit 1 are retained while clock signal CK is in the low level. On the other hand, the output signals transferred from master circuit 1 to slave circuit 2 are inverted by the differential pair made up of transistors Q10 and Q11, and then level shifted by transistors Q17 and Q18 to be extracted at output terminals Q and QB of slave circuit 2. At this moment, since transistor Q15 is applied with clock signal CK being in the low level, hence is non-conductive, no current will flow through the differential pair made up of transistors Q12 and Q13. As a result, the signals extracted at output terminals Q and QB of master circuit 2 are held at output terminals Q and QB.

In this way, the signals extracted at output terminals Q and QB of slave circuit 2 repeat level inversion when clock signal CK changes from the high level to the low level.

In the static flip-flop circuit shown in FIG. 1, the delay time of master circuit 1 is given by the sum of time T1 taken from when clock signal CK is input until the data is output to the emitter follower circuit and time T2 until the differential pair (transistors Q3 and Q4) having positive feedback and the input differential pair (transistors Q10 and Q11) at the following slave circuit 2 are actuated. The shorter the delay time, the faster will the static flip-flop circuit operate. Delay time T2 is markedly affected by the Miller capacitances of the differential pair (transistors Q3 and Q4) having positive feedback and the input differential pair (transistors Q10 and Q11) of the following, slave circuit 2.

Japanese Patent Application Laid-open 1993-48402 discloses a static flip-flop circuit which can operate at high speed by reducing the Miller capacitance of the differential pair (transistors Q3 and Q4) having positive feedback, among the Miller capacitances associated with the aforementioned delay time T2.

Referring to FIG. 2, in the static flip-flop circuit disclosed in the above patent publication, transistor Q5 of master circuit 1 and transistor Q14 of slave circuit 2 are arranged so as to form a differential pair, whose common emitters are connected to transistor Q7 and resistor R5, which constitute a current source circuit. Also, transistor Q6 of master circuit 1 and transistor Q15 of slave circuit 2 are arranged so as to form another differential pair, whose common emitters are connected to transistor Q16 and resistor R8, which constitute a current source circuit.

In this way, in the static flip-flop circuit shown in FIG. 2, the data reading circuitry and the data-hold positive-feedback circuitry are separated from each other, each including an individual current source circuit, so that individual transistors Q7 and Q16 are provided to implement current switching between the master circuit side and the slave circuit side. This arrangement makes it possible to design the flip-flop with which the current passing through the data-hold positive-feedback circuit is suppressed compared to that passing through the data reading circuit.

Miller capacitance Cm of a differential pair having positive feedback can be represented by:
Cm=Cc(1+Ao),
where Cc is the collector capacitance of the transistors included in that the differential pair and Ao the voltage amplification factor of the differential pair. Here, if the operating current of the transistors constituting the differential pair of the data-hold positive-feedback circuit is made small, voltage amplification factor Ao can be reduced, whereby it is possible to reduce Miller capacitance Cm of the differential pair of the data-hold positive-feedback circuit. As a result, of the aforementioned delay time T2, the delay time until for driving the differential pair of the data-hold positive-feedback circuit can be shortened, and the static flip-flop circuit can be operated at a higher speed for that.

With the static flip-flop circuit shown in FIG. 2, it is possible to reduce the operating currents of the differential pairs of the data-hold positive-feedback circuits, independently, by combining the data reading circuit and the data-hold positive-feedback circuit in the master circuit and the slave circuit. This circuit configuration, however, not only complicates the circuit layout, but also increases the number of crossovers between signal lines, hence increasing parasitic capacitance between signal lines. This results in reduction of the inherent processing speed of the flip-flop circuit and increases jitters in the signal waveform.

It is therefore an object of the present invention to provide a static flip-flop circuit which is able to operate at high speed by reducing the Miller capacitance of the differential pairs of the data-hold positive-feedback circuits without use of an arrangement made up of individual transistors for current switching between the master circuit side and the slave circuit side.

### DISCLOSURE OF INVENTION

In order to attain the above object, a static flip-flop circuit of the present invention characterized in that it comprises: a master circuit including a first data reading differential pair, a first data-hold differential pair composed of transistors of a size smaller than the transistors constituting the first data reading differential pair, and a first current source circuit connected to the first data reading differential pair and the first data-hold differential pair; and a slave circuit including a second data reading differential pair, a second data-hold differential pair composed of transistors of a size smaller than the transistors constituting the second data reading differential pair, and a second current source circuit connected to the second data reading differential pair and the second data-hold differential pair, wherein the flip-flop circuit operates in an operating speed range in which the currents through the first and second data-hold differential pairs are lower than the currents through the first and second data reading differential pairs, and the currents through the first and second data-hold differential pairs are equal to or lower than the permissible current level of the transistors that constitute the data-hold differential pairs.

According to the present invention, from the fact that the currents through the data-hold differential pairs are low and from the fact that the transistors constituting the data-hold differential pairs are small in size, the voltage amplification factor Ao of the data-hold differential pair and the collector capacitance Cc become small. This leads to reduction of Miller capacitance Cm of the data-hold differential pairs, thus making it possible to achieve high speed operation of the static flip-flop circuit.

Further, also in the low-speed operation range, the currents through the data-hold differential pairs may be controlled to be equal to or lower than the permissible current level of the transistors that constitute the data-hold differential pairs, so that it is possible to operate the flip-flop circuit across the wide range from the maximum speed to the low speed range.

### BRIEF DESCRIPTION OF DRAWINGS

FIG. 1 is a circuit diagram showing an example of a conventional static flip-flop circuit.

FIG. 2 is a circuit diagram showing another example of a conventional static flip-flop circuit.

FIG. 3 is a circuit diagram showing a static flip-flop circuit according to the first embodiment of the present invention.

FIG. 4A is a characteristic chart for illustrating the operation/behavior and operation conditions at the low-speed operation mode of a static flip-flop circuit according to the first embodiment of the present invention.

FIG. 4B is a characteristic chart for illustrating the operation/behavior and operation conditions at the high-speed operation mode of a static flip-flop circuit according to the first embodiment of the present invention.

FIG. 5 is a circuit diagram showing a static flip-flop circuit according to the second embodiment of the present invention.

FIG. 6 is a characteristic chart for illustrating the operation and operation conditions of a static flip-flop circuit according to the second embodiment of the present invention.

FIG. 7 is a circuit diagram showing a static flip-flop circuit according to the third embodiment of the present invention.

FIG. 8 is a circuit diagram showing a static flip-flop circuit according to the fourth embodiment of the present invention.

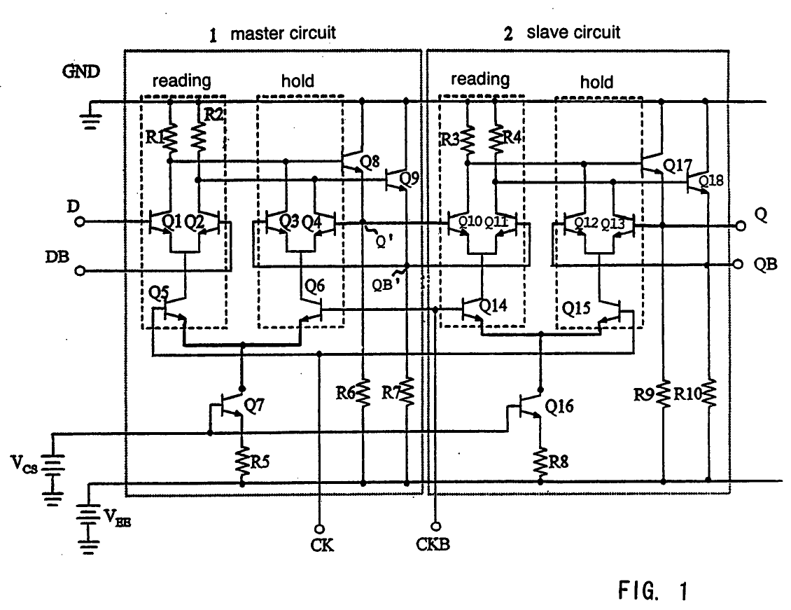

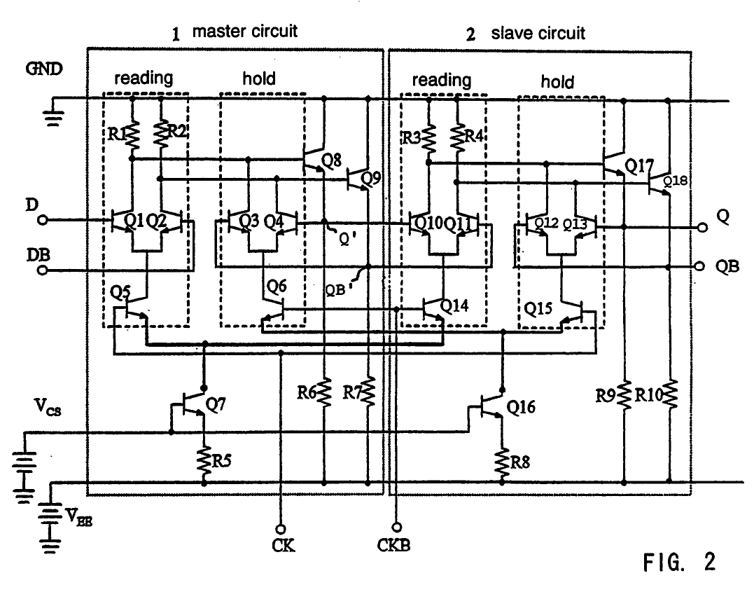

### BEST MODE FOR CARRYING OUT THE INVENTION

Preferred embodiments of the present invention will be described in detail with reference to the drawings.

### The First Embodiment

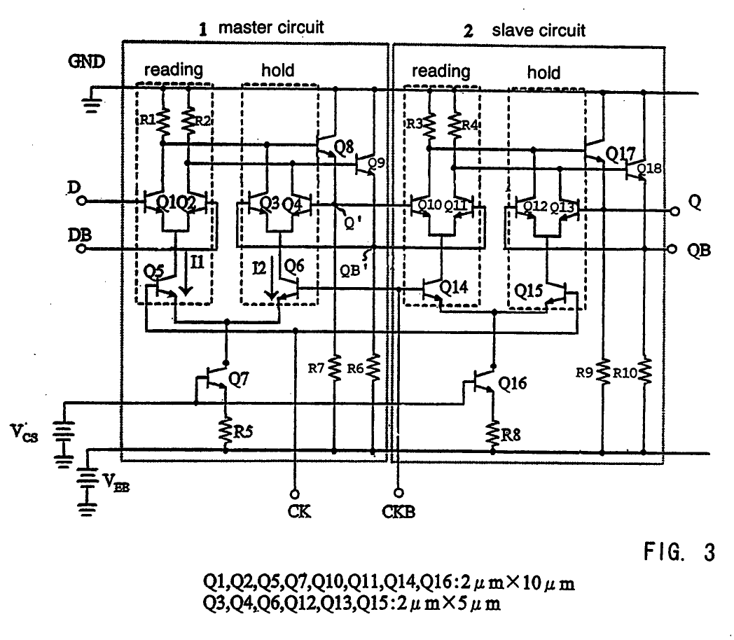

FIG. 3 is a circuit diagram showing a static flip-flop circuit according to the first embodiment of the present invention. The circuit configuration shown herein uses bipolar type transistors.

Referring to FIG. 3, the static flip-flop according to the first embodiment of the present invention includes two latch circuits, master circuit 1 and slave circuit 2. Here, GND represents a ground terminal and VEE represents a power supply terminal.

Master circuit 1 includes: a data reading circuit composed of resistors R1 and R2 and transistors Q1, Q2 and Q5; a data-hold positive-feedback circuit composed of resistors R1 and R2, transistors Q3, Q4 and Q6, transistors Q8 and Q9 and resistors R6 and R7; and a current source circuit composed of transistor Q7 connected to the common emitters of transistors Q5 and Q6 and resistor R5.

Slave circuit 2 includes: a data reading circuit composed of resistors R3 and R4 and transistors Q10, Q11 and Q14; a data-hold positive-feedback circuit composed of resistors R3 and R4, transistors Q12, Q13 and Q15, transistors Q17 and Q18 and resistors R9 and R10; and a current source circuit composed of transistor Q16 connected to the common emitters of transistors Q14 and Q15 and resistor R8.

The transistors (transistors Q3, Q4, Q6, Q12, Q13 and Q15) constituting the data-hold differential pairs are designed to be smaller in size than the transistors (transistors Q1, Q2, Q5, Q10, Q11 and Q14) constituting the data reading differential pairs. In FIG. 3, the data reading differential pairs use transistors having an emitter size of 2 μm×10 μm whereas the data-hold differential pairs use transistors having an emitter size of 2 μm×5 μm. For transistors Q7 and Q16, transistors having an emitter size of 2 μm×10 μm are used similarly to those for the data reading differential pairs.

The current source circuit for master circuit 1 and the current source circuit for slave circuit 2 are connected to common constant-current source terminal VCS so that a constant current will flow through each current source circuit.

Next, the operation and operating conditions of the static flip-flop circuit according to the first embodiment of the present invention shown in FIG. 3 will be described.

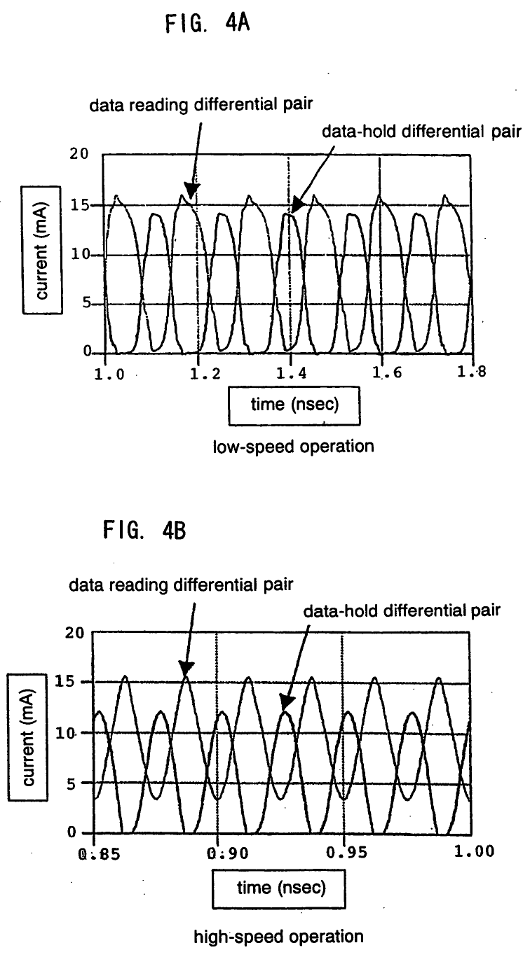

FIGS. 4A and 4B are the characteristic charts showing the variations of the current through the data reading differential pairs and the current through the data-hold differential pairs in two operating speed ranges (the low-speed operation range and the high-speed operation range).

Since the data reading circuit and the data-hold positive-feedback circuit are connected to common constant-current source terminal VCS via the common current source circuit, in the low-speed operation range (FIG. 4A) the current through the data reading differential pair and the current through data-hold differential pair vary within substantially the same operation current.

On the other hand, in the high-speed operation range (FIG. 4B), the current through the data-hold differential pair decreases, becoming lower than the current through the data reading differential pair. Though the sum of the current through the data-hold differential pair and the current through the data reading differential pair is constant without regard to the operating speed, the minimum current and the average current through the reading differential pair increase because the maximum current and the average current through the data-hold differential pair decrease.

In this way, depending on the operating speed of the flip-flop circuit, the currents through the data-hold differential pairs vary. Since the transistors constituting the data-hold differential pairs are configured to be smaller in size than the transistors constituting the data reading differential pairs, their current-carrying capacity is lower than that of the transistors constituting the data reading differential pair.

Based on the above fact, the flip-flop circuit is adapted to operate in the high-speed operation range in which the currents through the data-hold differential pairs are lower than the currents through the data reading differential pairs and the currents through the data-hold differential pairs are equal to or lower than the permissible current of the transistors constituting the data-hold differential pairs.

Operating the flip-flop circuit within the above operating speed range can prevent an excessive current from flowing through the data-hold differential pairs. Further, from the fact that the voltage amplification factor Ao of the data-hold differential pairs becomes smaller due to decrease of the current through data-hold differential pair, and from the fact that the collector capacitance Cc becomes smaller because the data-hold differential pair is formed by small-sized transistors, the voltage amplification factor Ao and collector capacitance Cc of the data-hold differential pairs become smaller. This leads to reduction of Miller capacitance Cm of the data-hold differential pairs, thus making it possible to achieve high speed operation of the static flip-flop circuit.

Though, in the description of the embodiment, the example involving bipolar transistors was taken, it is also possible to realize the static flip-flop circuit of this embodiment similarly when, for example, GaAs MESFETs (Metal Semiconductor Field Effect Transistors) are employed.

Further, description was made taking an example of a D-type flip-flop circuit, but it is also possible to realize the static flip-flop circuit of this embodiment similarly with a T-type flip-flop circuit configuration that can provide a frequency dividing function by feeding back the output from the slave circuit to the data input of the master circuit.

### The Second Embodiment

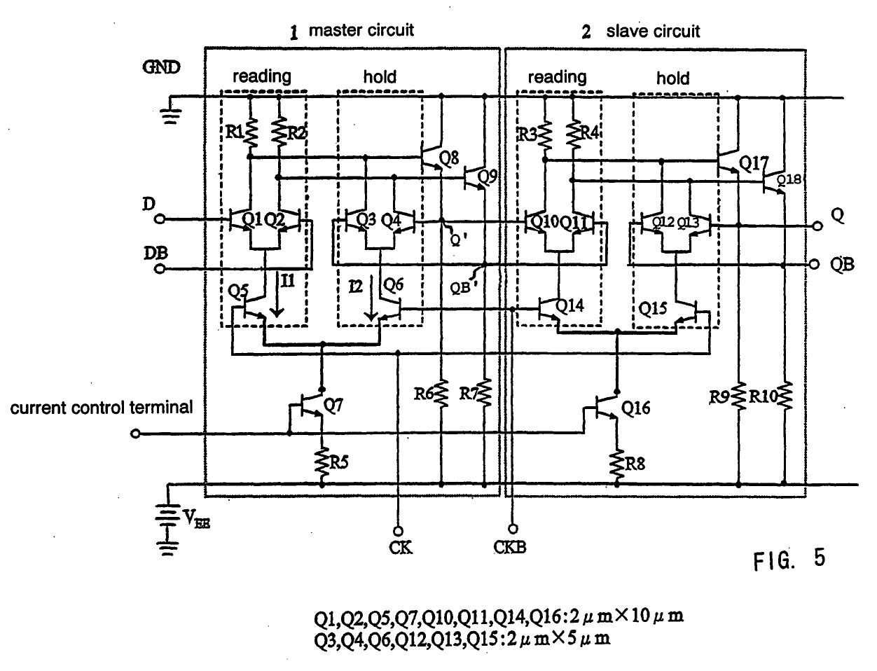

FIG. 5 is a circuit diagram showing a static flip-flop circuit according to the second embodiment of the present invention. The circuit configuration shown herein uses bipolar type transistors.

Referring to FIG. 5, the static flip-flop according to the second embodiment of the present invention includes two latch circuits, master circuit 1 and slave circuit 2. Here, GND represents a ground terminal and VEE represents a power supply terminal.

Master circuit 1 includes: a data reading circuit composed of resistors R1 and R2 and transistors Q1, Q2 and Q5; a data-hold positive-feedback circuit composed of resistors R1 and R2, transistors Q3, Q4 and Q6, transistors Q8 and Q9 and resistors R6 and R7; and a current source circuit composed of transistor Q7 connected to the common emitters of transistors Q5 and Q6 and resistor R5.

Slave circuit 2 includes: a data reading circuit composed of resistors R3 and R4 and transistors Q10, Q11 and Q14; a data-hold positive-feedback circuit composed of resistors R3 and R4, transistors Q12, Q13 and Q15, transistors Q17 and Q18 and resistors R9 and R10; and a current source circuit composed of transistor Q16 connected to the common emitters of transistors Q14 and Q15 and resistor R8.

The above first embodiment is constructed so that the current source circuit of master circuit 1 and the current source circuit of slave circuit 2 are connected to constant-current source terminal VCS and a constant current flows through each current source circuit.

In contrast, in this embodiment the current source circuit of master circuit 1 and the current source circuit of slave circuit 2 are connected to a current control terminal, so that this current control terminal will control the current flowing through each current source circuit in accordance with the operating speed of the flip-flop circuit.

The transistors (transistors Q3, Q4, Q6, Q12, Q13 and Q15) constituting the data-hold differential pairs are designed to be smaller in size than the transistors (transistors Q1, Q2, Q5, Q10, Q11 and Q14) constituting the data reading differential pairs. In FIG. 5, the data reading differential pairs use transistors having an emitter size of 2 μm×10 μm whereas the data-hold differential pairs use transistors having an emitter size of 2 μm×5 μm. For transistors Q7 and Q16, transistors having an emitter size of 2 μm×10 μm are used similarly to those for the data reading differential pairs.

Next, the operation and operating conditions of the static flip-flop circuit according to the second embodiment of the present invention shown in FIG. 5 will be described.

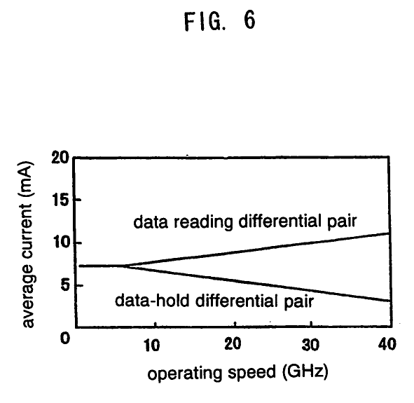

FIG. 6 shows the characteristic chart representing the dependence of the average current for the data reading differential pairs, and the dependence of the average current for the data-hold differential pairs, upon the operating speed of the flip-flop circuit.

In the high-speed operation range, the currents through the data-hold differential pairs are lower than the currents through the data reading differential pairs. In this case, the flip-flop circuit is controlled by the current control terminal so that the maximum current through the data-hold differential pairs will be equal to or lower than the permissible current of the transistors constituting the data-hold differential pairs. Accordingly, from the fact that the currents through the data-hold differential pairs are low and from the fact that the transistors constituting the data-hold differential pairs are small in size, the voltage amplification factor Ao of the data-hold differential pairs and the collector capacitance Cc become small, whereby it is possible to achieve high speed operation of the static flip-flop circuit.

In the low-speed operation range, though the currents through the data-hold differential pairs increase to as high as the currents through the data reading differential pairs, the maximum current through the data-hold differential pairs may be controlled by the current control terminal so as to be equal to or lower than the permissible current of the transistors constituting the data-hold differential pairs.

As described above, in this embodiment, the current control terminal is used to control the currents through the data-hold differential pairs so as to be equal to or lower than the permissible current of the transistors, whereby it is possible to operate the flip-flop circuit across the wide range from the maximum speed to the low speed range.

Though, in the description of the embodiment, the example involving bipolar transistors was taken, it is also possible to realize the static flip-flop circuit of this embodiment similarly when, for example, GaAs MESFETs are employed.

Further, description was made taking an example of a D-type flip-flop circuit, but it is also possible to realize the static flip-flop circuit of this embodiment similarly with a T-type flip-flop circuit configuration that can provide a frequency dividing function by feeding back the output from the slave circuit to the data input of the master circuit.

### The Third Embodiment

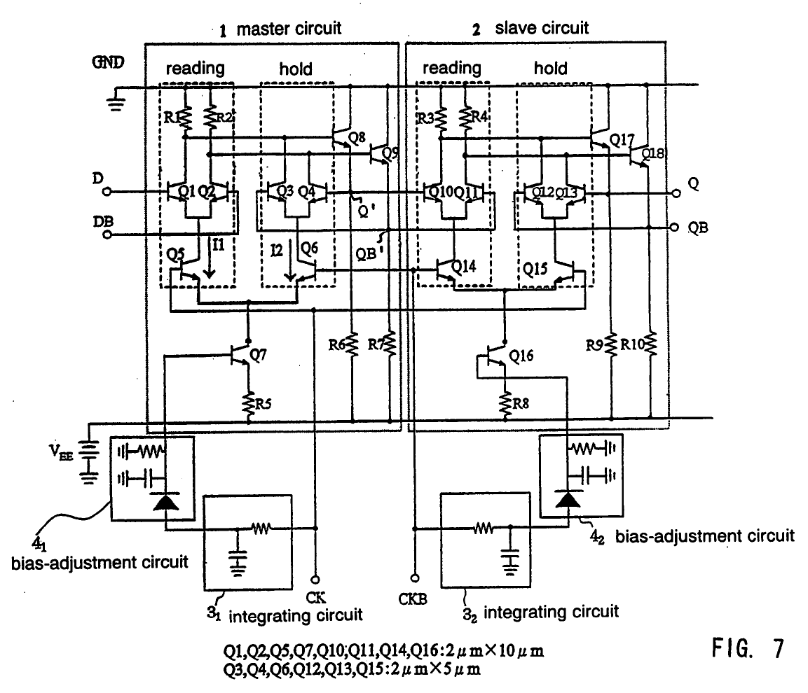

FIG. 7 is a circuit diagram showing a static flip-flop circuit according to the third embodiment of the present invention. The circuit configuration shown herein uses bipolar type transistors.

Referring to FIG. 7, the static flip-flop according to the third embodiment of the present invention includes two latch circuits, master circuit 1 and slave circuit 2. Here, GND represents a ground terminal and VEE represents a power supply terminal.

Master circuit 1 includes: a data reading circuit composed of resistors R1 and R2 and transistors Q1, Q2 and Q5; a data-hold positive-feedback circuit composed of resistors R1 and R2, transistors Q3, Q4 and Q6, transistors Q8 and Q9 and resistors R6 and R7; and a current source circuit composed of transistor Q7 connected to the common emitters of transistors Q5 and Q6 and resistor R5.

Slave circuit 2 includes: a data reading circuit composed of resistors R3 and R4 and transistors Q10, Q11 and Q14; a data-hold positive-feedback circuit composed of resistors R3 and R4, transistors Q12, Q13 and Q15, transistors Q17 and Q18 and resistors R9 and R10; and a current source circuit composed of transistor Q16 connected to the common emitters of transistors Q14 and Q15 and resistor R8.

Connected between transistor Q7 that forms the current source circuit of master circuit 1 and implements current switching and the terminal to which clock signal CK is input are integrating circuit 3₁ made up of resistance and capacitance and bias-adjustment circuit 4₁ including a diode. Further, integrating circuit 3₂ and bias-adjustment circuit 4₂, similar to the above, are connected between transistor Q16 that forms the current source circuit of slave circuit 2 and implements current switching and the terminal to which complementary clock signal CKB is input.

The transistors (transistors Q3, Q4, Q6, Q12, Q13 and Q15) constituting the data-hold differential pairs are designed to be smaller in size than the transistors (transistors Q1, Q2, Q5, Q10, Q11 and Q14) constituting the data reading differential pairs. In FIG. 7, the data reading differential pairs use transistors having an emitter size of 2 μm×10 μm whereas the data-hold differential pairs use transistors having an emitter size of 2 μm×5 μm. For transistors Q7 and Q16, transistors having an emitter size of 2 μm×10 μm are used similarly to those for the data reading differential pairs.

Next, the operation and operating conditions of the static flip-flop circuit according to the third embodiment of the present invention shown in FIG. 7 will be described.

When the frequency of clock signal CK and complementary clock signal CKB is sufficiently higher than the cutoff frequencies of integrating circuits 31 and 32, a certain level of voltage is applied to transistors Q7 and Q16 which are the components of the current source circuits of master circuit 1 and slave circuit 2. At such a frequency, the flip-flop circuit is set up so that the maximum current through the data-hold differential pairs will be lower than the currents through the data reading differential pairs and the maximum current through the data-hold differential pairs will be equal to or lower than the permissible current of the transistors constituting the data-hold differential pairs. Accordingly, from the fact that the currents through the data-hold differential pairs are low and from the fact that the transistors constituting the data-hold differential pairs are small in size, the voltage amplification factor Ao of the data-hold differential pairs and the collector capacitance Cc become small, whereby it is possible to achieve high speed operation of the static flip-flop circuit.

As the frequency of clock signal CK and complementary clock signal CKB lowers, the outputs from integrating circuits 3₁ and 3₂ are synchronized with clock signal CK and complementary clock signal CKB. Specifically, amplitudes of the outputs from integrating circuits 3, and 32 become greater as the frequency of clock signal CK and complementary clock signal CKB lowers. Under this condition, with the high levels being fixed at constant, the low levels of the output signals from integrating circuits 3₁ and 3₂ are adapted to vary in accordance with the frequency of clock signal CK and complementary clock signal CKB. This makes automatically reduces the currents through the data-hold differential pairs in accordance with the frequency of clock signal CK and complementary clock signal CKB, hence makes it possible to constantly control the current through the transistors to be equal to or lower than the permissible level.

As described above, in this embodiment, integrating circuits 3₁ and 3₂, which branch off respectively from the terminal to which clock signal CK is input and from the terminal to which complementary clock signal CKB is input, are used to automatically control the currents through the data-hold differential pairs so as to be equal to or lower than the permissible current of the transistors, whereby the flip-flop circuit can be operated across the wide range from the maximum speed to the low speed range.

Though, in the description of the embodiment, circuits consisting of resistance and capacitance are used as integrating circuits 3₁ and 3₂, the static flip-flop circuit of the present embodiment can be realized in a similar manner when other integrating circuits or low-pass filter circuits are used. Further, through circuits including a diode are used for bias-adjustment circuits 4₁ and 4₂, the static flip-flop circuit of the present embodiment can be realized in a similar manner when another type of bias-adjustment circuit is used.

Though, in the description of the embodiment, the example involving bipolar transistors was taken, it is also possible to realize the static flip-flop circuit of this embodiment similarly when, for example, GaAs MESFETs are employed.

Further, description was made taking an example of a D-type flip-flop circuit, but it is also possible to realize the static flip-flop circuit of this embodiment similarly with a T-type flip-flop circuit configuration that can provide a frequency dividing function by feeding back the output from the slave circuit to the data input of the master circuit.

### The Fourth Embodiment

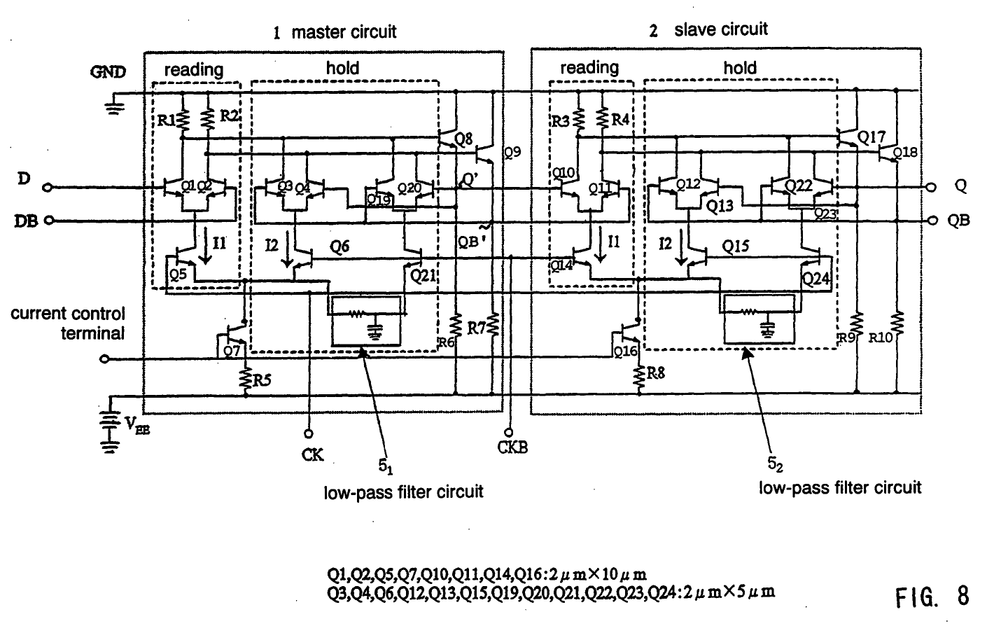

FIG. 8 is a circuit diagram showing a static flip-flop circuit according to the fourth embodiment of the present invention. The circuit configuration shown herein uses bipolar type transistors.

Referring to FIG. 8, the static flip-flop according to the fourth embodiment of the present invention includes two latch circuits, master circuit 1 and slave circuit 2. Here, GND represents a ground terminal and VEE represents a power supply terminal.

Master circuit 1 includes: a data reading circuit composed of resistors R1 and R2 and transistors Q1, Q2 and Q5; a data-hold positive-feedback circuit composed of resistors R1 and R2, transistors Q3, Q4, Q6, Q19, Q20 and Q21, transistors Q8 and Q9 and resistors R6 and R7; and a current source circuit composed of transistor Q7 connected to the common emitters of transistors Q5 and Q6 and resistor R5.

Slave circuit 2 includes: a data reading circuit composed of resistors R3 and R4 and transistors Q10, Q11 and Q14; a data-hold positive-feedback circuit composed of resistors R3 and R4, transistors Q12, Q13, Q15 Q22, Q23 and Q24, transistors Q17 and Q18 and resistors R9 and R10; and a current source circuit composed of transistor Q16 connected to the common emitters of transistors Q14 and Q15 and resistor R8.

The data-hold differential pair of master circuit 1 is composed of two differential pairs connected in parallel, and the emitters of transistor Q6 and transistor Q21 are connected to each other with low-pass filter circuit 5₁ consisting of resistance and capacitance interposed therebetween. The data-hold differential pair of slave circuit 2 is composed of two differential pairs connected in parallel, and the emitters of transistor Q15 and transistor Q24 are connected to each other with low-pass filter circuit 52 consisting of resistance and capacitance interposed therebetween.

The transistors (transistors Q3, Q4, Q6, Q19, Q20, Q21, Q12, Q13, Q15, Q22, Q23 and Q24) constituting the data-hold differential pairs are designed to be smaller in size than the transistors (transistors Q1, Q2, Q5, Q10, Q11 and Q14) constituting the data reading differential pairs. In FIG. 8, the data reading differential pairs use transistors having an emitter size of 2 μm×10 μm whereas the data-hold differential pairs use transistors having an emitter size of 2 μm×5 μm. For transistors Q7 and Q16, transistors having an emitter size of 2 μm×10 μm are used similarly to those for the data reading differential pairs.

Next, the operation and operating conditions of the static flip-flop circuit according to the fourth embodiment of the present invention shown in FIG. 8 will be described.

When the frequency of clock signal CK and complementary clock signal CKB is sufficiently higher than the cutoff frequencies of low-pass filter circuits 5₁ and 5₂, in the data-hold differential pairs each being composed of two differential pairs connected in parallel, current only flows through the differential pairs constituted of transistors Q3, Q4 and Q6 and transistors Q12, Q13 and Q15 while no current flows through transistors Q19, Q20 and Q21 and through transistors Q22, Q23 and Q24 connected respectively to low-pass filter circuit 5₁ and 5₂. At such a frequency, the flip-flop circuit is set up so that the current through the data-hold differential pairs will be lower than the currents through the data reading differential pairs and the maximum current through the data-hold differential pairs will be equal to or lower than the than the permissible current of the transistors constituting that data-hold differential pairs. Accordingly, from the fact that the currents through the data-hold differential pairs are low and from the fact that the transistors constituting the data-hold differential pairs are small in size, the voltage amplification factor Ao of the data-hold differential pairs and the collector capacitance Cc become small, whereby it is possible to achieve high speed operation of the static flip-flop circuit.

As the frequency of clock signal CK and complementary clock signal CKB lowers, current flowing through the data-hold differential pairs increases, and however no excessive current above the permissible current level will flow through the transistors of the differential pairs constituted of transistors Q3, Q4 and Q6 and transistors Q12, Q13 and Q15, since current also flows through the other differential pairs constituted of transistors Q19, Q20 and Q21 and transistors Q22, Q23 and Q24 connected to low-pass filter circuit 5₁ and 5₂.

When the frequency of clock signal CK and complementary clock signal CKB becomes sufficiently lower than the cut-off frequencies of low-pass filter circuits 5₁ and 5₂, each data-hold differential pair composed of two differential pairs connected in parallel becomes equivalent to a data-hold differential pair composed of double-sized transistors. Therefore, if the current flowing through the data-hold differential pair increases, the current through the data-hold differential pair will not exceed the permissible current of the transistors constituting that data-hold differential pair.

As described above, in this embodiment, each data-hold differential pair is configured of two differential pairs connected in parallel to each other with low-pass filter circuit 5₁ or 5₂ interposed therebetween, so that it is possible to control the currents passing through the data-hold differential pairs in accordance with clock signal CK and complementary clock signal CKB, whereby it is possible to operate the flip-flop circuit across the wide range from the maximum speed to the low speed range.

Though, in the description of the embodiment, circuits consisting of resistance and capacitance are used as low-pass filter circuits 5₁ and 5₂, the static flip-flop circuit of the present embodiment can be realized in a similar manner when other low-pass circuits or inductors or distributed lines are used.

Though, in the description of the embodiment, the example involving bipolar transistors was taken, it is also possible to realize the static flip-flop circuit of this embodiment similarly when, for example, GaAs MESFETs are employed.

Further, description was made taking an example of a D-type flip-flop circuit, but it is also possible to realize the static flip-flop circuit of this embodiment similarly with a T-type flip-flop circuit configuration that can provide a frequency dividing function by feeding back the output from the slave circuit to the data input of the master circuit.

1. A static flip-flop circuit characterized in that it comprises:
a master circuit including a first data reading differential pair, a first data-hold differential pair composed of transistors of a size smaller than the transistors constituting the first data reading differential pair, and a first current source circuit connected to the first data reading differential pair and the first data-hold differential pair; and
a slave circuit including a second data reading differential pair, a second data-hold differential pair composed of transistors of a size smaller than the transistors constituting the second data reading differential pair, and a second current source circuit connected to the second data reading differential pair and the second data-hold differential pair,
wherein the flip-flop circuit operates in an operating speed range in which the currents through the first and second data-hold differential pairs are lower than the currents through the first and second data reading differential pairs, and the currents through the first and second data-hold differential pairs are equal to or lower than the permissible current level of the transistors that constitute the data-hold differential pairs.

2. A static flip-flop circuit characterized in that it comprises:
a master circuit including a first data reading differential pair, a first data-hold differential pair composed of transistors of a size smaller than the transistors constituting the first data reading differential pair, and a first current source circuit connected to the first data reading differential pair and the first data-hold differential pair;
a slave circuit including a second data reading differential pair, a second data-hold differential pair composed of transistors of a size smaller than the transistors constituting the second data reading differential pair, and a second current source circuit connected to the second data reading differential pair and the second data-hold differential pair; and
a current control terminal connected to the first and second current source circuits for controlling the currents through the first and second data reading differential pairs and the currents through the first and second data-hold differential pairs, in accordance with the operating speed of the flip-flop circuit.

3. The static flip-flop circuit according to claim 2, wherein, when the operating speed of the flip-flop circuit lowers from the maximum operating speed, the current control terminal adjusts the currents through the first and second data-hold differential pairs to be equal to or lower than the permissible current level of the transistors constituting the data-hold differential pairs.

4. A static flip-flop circuit characterized in that it comprises:
a master circuit including a first data reading differential pair, a first data-hold differential pair composed of transistors of a size smaller than the transistors constituting the first data reading differential pair, and a first current source circuit connected to the first data reading differential pair and the first data-hold differential pair;
a slave circuit including a second data reading differential pair, a second data-hold differential pair composed of transistors of a size smaller than the transistors constituting the second data reading differential pair, and a second current source circuit connected to the second data reading differential pair and the second data-hold differential pair;
a first integrating circuit interposed between the first current source circuit for the master circuit and the terminal to which a clock signal is input; and
a second integrating circuit interposed between the second current source circuit for the slave circuit and the terminal to which a complementary clock signal is input.

5. The static flip-flop circuit according to claim 4, wherein, when the operating speed of the flip-flop circuit lowers from the maximum operating speed, the first and second integrating circuits adjust the currents through the first and second data-hold differential pairs to be equal to or lower than the permissible current level of the transistors constituting the data-hold differential pairs.

6. A static flip-flop circuit characterized in that it comprises:
a master circuit including a first data reading differential pair, a first data-hold differential pair composed of transistors of a size smaller than the transistors constituting the first data reading differential pair, and a first current source circuit connected to the first data reading differential pair and the first data-hold differential pair;
a slave circuit including a second data reading differential pair, a second data-hold differential pair composed of transistors of a size smaller than the transistors constituting the second data reading differential pair, and a second current source circuit connected to the second data reading differential pair and the second data-hold differential pair;
a first low-pass filter circuit interposed between the first current source circuit for the master circuit and the terminal to which a clock signal is input; and
a second low-pass filter circuit interposed between the second current source circuit for the slave circuit and the terminal to which a complementary clock signal is input.

7. The static flip-flop circuit according to claim 6, wherein, when the operating speed of the flip-flop circuit lowers from the maximum operating speed, the first and second low-pass filter circuits adjust the currents through the first and second data-hold differential pairs to be equal to or lower than the permissible current level of the transistors constituting the data-hold differential pairs.

8. A static flip-flop circuit characterized in that it comprises:
a master circuit including a first data reading differential pair, a first data-hold differential pair composed of two differential pairs, having transistors of a size smaller than the transistors constituting the first data reading differential pair, and connected to each other in parallel via a first low-pass filter circuit, and a first current source circuit connected to the first data reading differential pair and the first data-hold differential pair; and
a slave circuit including a second data reading differential pair, a second data-hold differential pair composed of two differential pairs, having transistors of a size smaller than the transistors constituting the second data reading differential pair, and connected to each other in parallel via a second low-pass filter circuit, and a second current source circuit connected to the second data reading differential pair and the second data-hold differential pair.

9. The static flip-flop circuit according to claim 8, wherein, when the operating speed of the flip-flop circuit lowers from the maximum operating speed, the first and second low-pass filter circuits adjust the currents through the first and second data-hold differential pairs to be equal to or lower than the permissible current level of the transistors constituting the data-hold differential pairs.

10. A static flip-flop circuit characterized in that it comprises:
a master circuit including a first data reading differential pair, a first data-hold differential pair composed of two differential pairs, having transistors of a size smaller than the transistors constituting the first data reading differential pair, and connected to each other in parallel via a first circuit including inductance, and a first current source circuit connected to the first data reading differential pair and the first data-hold differential pair; and
a slave circuit including a second data reading differential pair, a second data-hold differential pair composed of two differential pairs, having transistors of a size smaller than the transistors constituting the second data reading differential pair, and connected to each other in parallel via a second circuit including inductance, and a second current source circuit connected to the second data reading differential pair and the second data-hold differential pair.

11. The static flip-flop circuit according to claim 10, wherein, when the operating speed of the flip-flop circuit lowers from the maximum operating speed, the first and second circuits adjust the currents through the first and second data-hold differential pairs to be equal to or lower than the permissible current level of the transistors constituting the data-hold differential pairs.

12. The static flip-flop circuit according to any one of claims 4, 6, 8 and 10, wherein, when the operating speed of the flip-flop circuit lowers from the maximum operating speed, the currents through the first and second data-hold differential pairs are adjusted to be equal to or lower than the permissible current level of the transistors constituting the data-hold differential pairs, depending on the operating speed.

13. The static flip-flop circuit according to any one of claims 1, 2, 4 and 6, wherein, when the operating speed of the flip-flop circuit lowers from the maximum operating speed, the currents through the first and second data-hold differential pairs increase, and at the minimum operating speed the current through the first data-hold differential pair becomes equal to the current through the first data reading differential pair and the current through the second data-hold differential pair becomes equal to the current through the second data reading differential pair.

14. The static flip-flop circuit according to any one of claims 1, 2, 4 and 6, wherein the sum of the current through the first data-hold differential pair and the current through the first data reading differential pair is equal to the current of the first current source circuit, and the sum of the current through the second data-hold differential pair and the current through the second data reading differential pair is equal to the current of the second current source circuit.
